(19) United States
(12) Patent Application Publication
(10) Pub. No.: US 2010/0195416 A1
(43) Pub. Date: Aug. 5, 2010

(54) Anti-fuse circuit and semiconductor memory device

(75) Inventor: Hiroshi Akamatsu, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/656,486

(22) Filed: Feb. 1, 2010

(30) Foreign Application Priority Data
Feb. 4, 2009 (JP) 2009-024176

(51) Int. Cl. G11C 7/00; H03K 19/0175; G11C 17/16

(52) U.S. Cl. 365/189.11; 326/80; 365/225.7; 365/226

(57) ABSTRACT

An anti-fuse circuit uses first to fifth power supplies which have first to fifth power supply voltages, respectively, in the order of highest to lowest during writing. The anti-fuse circuit includes: a first level shift circuit which is connected to the second to fourth power supplies and which converts a first logic signal that changes between the third and fourth power supply voltages into a second logic signal that changes between the second and fourth power supply voltages; a second level shift circuit which is connected to the first, second, and fourth power supplies and which converts the second logic signal into a third logic signal that changes between the first and fourth power supply voltages; a transistor having a source connected to the first power supply and a gate connected to the third logic signal; and an anti-fuse element having one end connected to the drain of the transistor and the other end connected to the fifth power supply.

### REFERENCE TO RELATED APPLICATION

This application is based upon and claims the benefit of the priority of Japanese patent application No. 2009-024176 filed on Feb. 4, 2009, the disclosure of which is incorporated herein in its entirety by reference thereto.

### FIELD OF THE INVENTION

The present invention relates to an anti-fuse circuit and a semiconductor memory device.

### BACKGROUND OF THE INVENTION

In the field of semiconductor devices, anti-fuse circuits are used. While these anti-fuse circuits are normally in an insulating state, when a high voltage is applied thereto and the insulating state is destroyed during a write operation, they are brought to be in a conducting state. Since anti-fuse circuits are programmed by destroying the insulating state thereof, writing can be executed only once. Namely, once data has been written, the written data cannot be replaced with original data. However, because of their lower resistance to conduction compared with other nonvolatile programming elements, anti-fuse circuits are widely used as field programmable gate arrays or non-volatile programmable circuits of other semiconductor devices.

In particular, as a circuit specifying replacement addresses of a redundant circuit used to relieve defective bits of a semiconductor memory and the like or a trimming circuit, a laser fuse is generally used. However, the laser fuse cannot be programmed after the semiconductor device is built in a package. On the other hand, since an anti-fuse circuit executes writing electrically, programming can be executed even after the semiconductor device is built in a package. Thus, anti-fuse circuits are drawing attention.

FIG. 1 illustrates a semiconductor device including a conventional anti-fuse circuit disclosed in FIG. 3 of Patent Document 1. Referring to FIG. 1, when programming an anti-fuse element 32, a high voltage (vpgm) is applied to one end of the anti-fuse element 32, and the other end of the anti-fuse element 32 is connected to ground (GND potential) via an N-channel protection transistor 34 and an N-channel driver transistor 38. Whether the anti-fuse element is allowed to undergo dielectric breakdown is determined based on a voltage applied to a gate of the N-channel driver transistor 38 which is selected by an address or the like.

Further, FIG. 2 illustrates a conventional anti-fuse circuit disclosed in FIG. 7 of Patent Document 2. Referring to FIG. 2, when programming an anti-fuse element AF1, a write voltage is applied to a terminal N11, and a high-level selection signal AFsel is supplied. When a transistor Q13 is turned on, a high voltage is applied to the anti-fuse element AF1, and a gate oxide film thereof is destroyed, whereby a current flows through the anti-fuse element AF1. Transistors Q11 and Q12 have a voltage dividing function, such that, when the transistor Q13 is not turned on for programming, a high voltage Vrr is not directly applied to the transistor Q13 and other circuits connected to a node N12 because of the coupling effect caused by the anti-fuse element AF1 having a capacitor structure.

Further, Patent Document 3 discloses a level shift circuit operable by only two systems of power supply voltages and having a great level shift capability.

### RELATED DOCUMENTS

[Patent Document]

Patent Document 1: Japanese Patent Kokai Publication No. 2002-134620 A

Patent Document 2: Japanese Patent Kokai Publication No. 2008-47215 A

Patent Document 3: Japanese Patent Kokai Publication No. 2004-363843 A

### SUMMARY

The entire disclosures of Patent Documents 1 to 3 are incorporated herein by reference thereto.

The following analyses are made based on the present invention. In the field of semiconductor integrated circuits such as semiconductor memory devices in which anti-fuse circuits are used, there are market demands for an increase of a system capacity and size and a decrease of power consumption. In response to these market demands, transistors are being fabricated in a smaller size, and a problem of withstand voltage decrease caused by microfabrication is being tackled. In addition, to facilitate lower power consumption, semiconductor integrated circuits are being configured to operate at a lower operating voltage. However, anti-fuse circuits need a circuit to apply a high voltage to a fuse element for a write programming operation.

According to a first aspect of the present invention, there is provided an anti-fuse circuit which uses first to fifth power supplies that have first to fifth power supply voltages, respectively, in the order of highest to lowest during writing. The anti-fuse circuit includes a first level shift circuit which is connected to the second to fourth power supplies and which converts a first logic signal that changes between the third and fourth power supply voltages into a second logic signal that changes between the second and fourth power supply voltages, a second level shift circuit which is connected to the first, second, and fourth power supplies and which converts the second logic signal into a third logic signal that changes between the first and fourth power supply voltages, a transistor having a first source/drain region connected to the first power supply and a gate connected to the third logic signal, and an anti-fuse element having one end connected to a second source/drain region of the transistor and the other end connected to the fifth power supply.

According to a second aspect of the present invention, there is provided a semiconductor memory device which includes a memory cell array and an anti-fuse circuit. The anti-fuse circuit uses first to fifth power supplies that have first to fifth power supply voltages, respectively, in the order of highest to lowest during writing. The anti-fuse circuit includes a first level shift circuit which is connected to the second to fourth power supplies and which converts a first logic signal that changes between the third and fourth power supply voltages into a second logic signal that changes between the second and fourth power supply voltages, a second level shift circuit which is connected to the first, second, and fourth power supplies and which converts the second logic signal into a third logic signal that changes between the first and fourth power supply voltages, a transistor having a source connected to the first power supply and a gate connected to the third logic signal, an anti-fuse element having one end connected to a drain of the transistor and the other end connected to the fifth power supply, a first voltage-boost circuit which increases the second power supply to a midpoint potential between the first power supply and the second power supply and applies the increased potential to the memory cell array, and a second voltage-boost circuit which further increases the potential increased by the first voltage-boost circuit to the first power supply when a write operation is executed on the anti-fuse circuit.

According to a third aspect of the present invention, there is provided a semiconductor device including, on a single semiconductor chip: a first level shift circuit receiving a logic signal which takes one of a first voltage and a second voltage larger than the first voltage and producing an intermediate signal which takes one of the first voltage and a third voltage larger than each of the first and second voltages; a second level shift circuit receiving the intermediate signal and producing a control signal which takes one of the first voltage and a fourth voltage larger than each of the first, second and third voltages; and an anti-fuse circuit including an anti-fuse element and receiving the fourth voltage, the anti-fuse circuit programming the anti-fuse element by supplying the fourth voltage to the anti-fuse element when the control signal takes the first voltage, and preventing the anti-fuse element from being supplied with the fourth voltage when the logic takes the fourth voltage.

According to the present invention, even when an anti-fuse is used in a circuit that operates at a low voltage, an anti-fuse circuit can be reliably written without causing any excessive stress on other circuits.

### BRIEF DESCRIPTION OF THE DRAWINGS

FIG. 1 illustrates a block diagram of a conventional anti-fuse programming circuit disclosed in Patent Document 1.

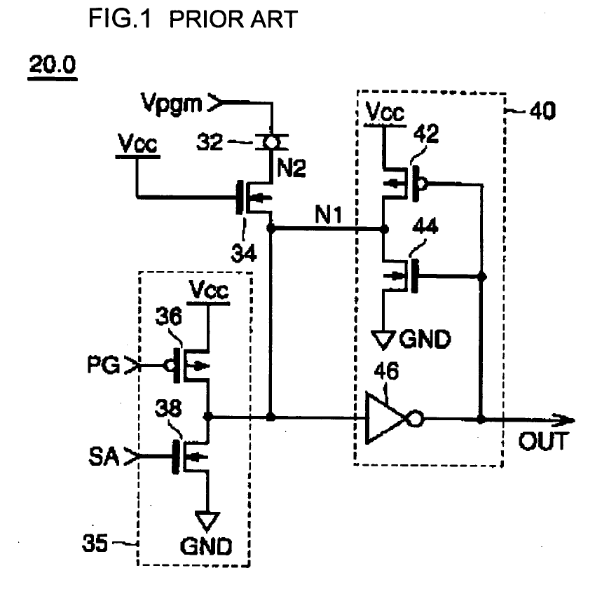

FIG. 2 illustrates another conventional anti-fuse writing circuit disclosed in Patent Document 2.

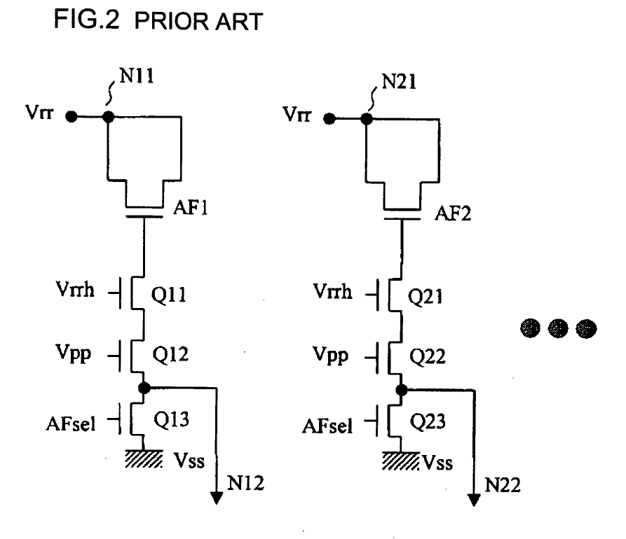

FIG. 3 illustrates an anti-fuse writing circuit according to an example of the present invention.

FIG. 4 illustrates an example of a level shift circuit.

FIG. 5 illustrates a block diagram of an entire semiconductor memory device according to another example of the present invention.

FIG. 6 illustrates power supply channels of a semiconductor memory device according to still another example of the present invention.

### PREFERRED MODES

Exemplary embodiments of the present invention will be hereinafter described with reference to the drawings as needed. The drawings and reference characters referred to in the description of the exemplary embodiments are used to illustrate examples of the exemplary embodiments. Therefore, variations of the exemplary embodiments according to the present invention are not limited by the drawings and reference characters.

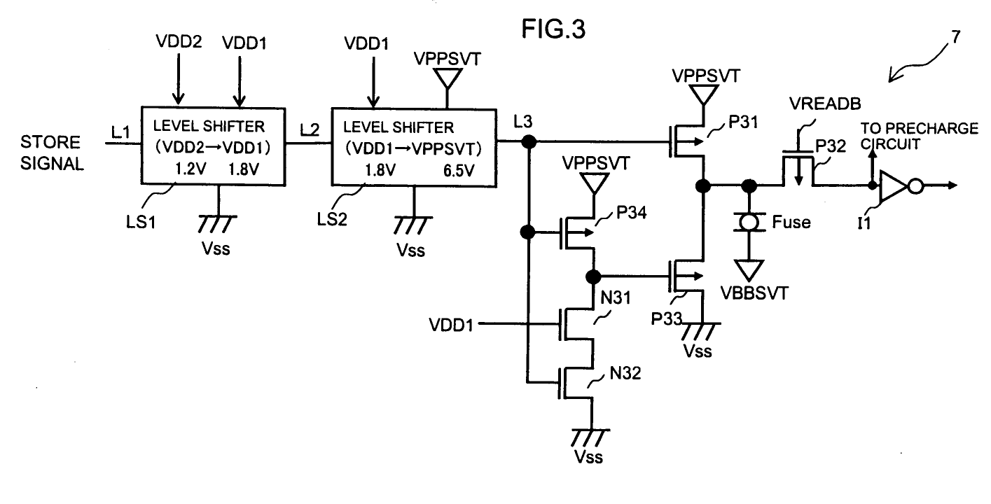

For example, as illustrated in FIG. 3, an anti-fuse circuit 7 according to an exemplary embodiment of the present invention is an anti-fuse circuit which uses first to fifth power supplies (VPPSVT, VDD1, VDD2, VSS, and VBBSVT) that have first to fifth power supply voltages, respectively, in the order of highest to lowest during writing (programming). The anti-fuse circuit 7 includes a first level shift circuit LS1 which is connected to the second to fourth power supplies (VDD1, VDD2, and VSS) and which converts a first logic signal L1 that changes between the third and fourth power supply voltages VDD2 and VSS into a second logic signal L2 that changes between the second and fourth power supply voltages VDD1 and VSS, a second level shift circuit LS2 which is connected to the first, second, and fourth power supplies (VPPSVT, VDD1, and VSS) and which converts the second logic signal L2 into a third logic signal L3 that changes between the first and fourth power supply voltages VPPSVT and VSS, a transistor P31 having a source connected to the first power supply VPPSVT and a gate connected to the third logic signal L3, and an anti-fuse element Fuse having one end connected to a drain of the transistor P31 and the other end connected to the fifth power supply VBBSVT. Based on the above configuration, the first level shift circuit LS1 and the second level shift circuit LS2 are used to increase a logical amplitude of the first logic signal L1 in two stages, and the logic signal L3 increased in this way is applied to the gate of the transistor P31 connected in series to the anti-fuse element Fuse. Since the logic signal L1 is increased in two stages to obtain the logic signal L3 applied to the gate, even when a logical amplitude of the initial logic signal is small, a sufficient operating margin can be secured. Further, since a large potential difference between the high voltage power supply VPPSVT and the low voltage power supply VBBSVT is used to execute a write operation on the anti-fuse element Fuse, it is possible to reduce voltage stress which is applied to peripheral circuits that operate at power supply voltages between the above high voltage power supply and the above low voltage power supply.

Further, for example, as shown in FIG. 3, the anti-fuse circuit 7 according to an exemplary embodiment of the present invention further includes, assuming that the transistor P31 is a first transistor P31, a second transistor P32 having a first source/drain region connected to one end of the anti-fuse element Fuse, a second source/drain region connected to a read circuit I1, and a gate connected to a control signal VREADB that turns off the second transistor P32 for writing and that turns on the second transistor P32 for reading. This second transistor P32 separates the read circuit I1 from the anti-fuse element Fuse during writing to prevent an excessive voltage from being applied to the read circuit I1. Also, the second transistor P32 connects the read circuit I1 to the anti-fuse element Fuse during reading, to detect whether the anti-fuse element Fuse is in a conductive state. The read circuit I1 operates in a VDD2 system and is supplied with the power supplies VDD2 and VSS.

Further, for example, as shown in FIG. 3, the anti-fuse circuit 7 according to an exemplary embodiment of the present invention further includes a third transistor P33 having a drain connected to the fourth power supply VSS and a source connected to the drain of the first transistor P31. A gate voltage of the third transistor P33 is controlled such that the third transistor P33 turns off and on when the first transistor P31 turns on and off, respectively, during writing.

Further, for example, as shown in FIG. 3, the anti-fuse circuit 7 according to the exemplary embodiment of the present invention further includes a fourth transistor P34 having a source connected to the first power supply VPPSVT, a gate connected to the third logic signal L3, and a drain connected to the gate of the third transistor P33, a fifth transistor N32 having a source connected to the fourth power supply VSS and a gate connected to the third logic signal L3, and a sixth transistor N31 having a source connected to a drain of the fifth transistor N32, a gate connected to the second power supply VDD1, and a drain connected to the drain the fourth transistor P34 and the gate of the third transistor P33. The first to fourth transistors (P31 to P34) are MOS transistors of a first conductivity type, and the fifth and sixth transistors (N32 and N31) are MOS transistors of a conductivity type opposite to the first conductivity type.

Further, based on the anti-fuse circuit 7 according to the exemplary embodiment of the present invention, the first power supply VPPSVT is not supplied during reading and both of the first and third transistors P31 and P33 are turned off.

Further, for example, as shown in FIGS. 3, 5, and 6, a semiconductor memory device according to an exemplary embodiment of the present invention includes a memory cell array 10 and an anti-fuse circuit 7. The anti-fuse circuit 7 uses first to fifth power supplies (VPPSVT, VDD1, VDD2, VSS, and VBBSVT) which have first to fifth power supply voltages, respectively, in the order of highest to lowest during writing. The anti-fuse circuit 7 includes a first level shift circuit LS1 which is connected to the second to fourth power supplies (VDD1, VDD2, and VSS) and which converts a first logic signal L1 that changes between the third and fourth power supply voltages VDD2 and VSS into a second logic signal L2 that changes between the second and fourth power supply voltages VDD1 and VSS, a second level shift circuit LS2 which is connected to the first, second, and fourth power supplies (VPPSVT, VDD1, and VSS) and which converts the second logic signal L2 into a third logic signal L3 that changes between the first and fourth power supply voltages VPPSVT and VSS, a transistor P31 having a source connected to the first power supply VPPSVT and a gate connected to the third logic signal L3, and an anti-fuse element Fuse having one end connected to a drain of the transistor P31 and the other end connected to the fifth power supply VBBSVT. A first voltage-boost circuit 20 increases the second power supply VDD1 to a midpoint potential VH between the first power supply VPPSVT and the second power supply VDD1 and applies the increased potential VH to the memory cell array 10 and a second voltage-boost circuit 22. When a write operation is executed on the anti-fuse circuit 7, the second voltage-boost circuit 22 further increases the potential VH increased by the first voltage-boost circuit 20 to the first power supply VPPSVT. Namely, the first voltage-boost circuit 20 can increase the second power supply VDD1 to a voltage necessary for a normal operation of the memory cell array 10, and the second voltage-boost circuit 22 can further increase the increased voltage to a voltage necessary for writing of the anti-fuse element Fuse.

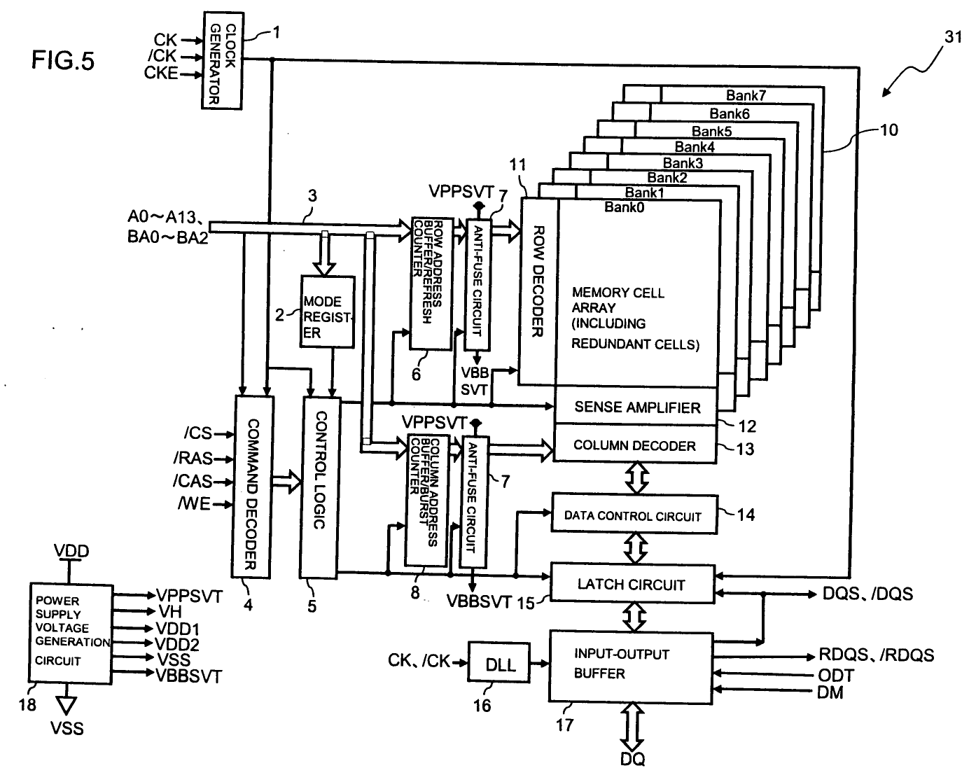

Further, for example, as shown in FIG. 5, based on the semiconductor memory device according to the exemplary embodiment of the present invention, the memory cell array 10 may include redundant cells, and the anti-fuse circuit 7 may be used to select the redundant cells. The present invention will be hereinafter described in detail based on examples with reference to the drawings.

### Example 1

FIG. 3 illustrates an anti-fuse writing circuit according to example 1, and a configuration and operations thereof will be hereinafter described. During a write operation, the anti-fuse writing circuit of FIG. 3 is supplied with five kinds of power supplies having power supply voltages VPPSVT, VDD1, VDD2, VSS, and VBBSVT in the order of highest to lowest. Preferably, VPPSVT is 6.5 V, VDD1; 1.8 V, VDD2; 1.2 V, VSS; 0 V, and VBBSVT; −3.5 V.

A STORE signal is a write data signal in the VDD2 system sent to an anti-fuse circuit 7. When the STORE signal is at a low level during a write operation, a current flows through an anti-fuse element Fuse, which is then brought to be in an on state. When the STORE signal is at a high level, since no current flows through the anti-fuse element Fuse, the anti-fuse element Fuse is maintained in a high impedance state. A level shifter LS1 is supplied with the power supplies VDD1, VDD2, and VSS and increases the STORE signal, which is a logic signal in the VDD2 system, to a logic signal L2 in the VDD1 system. Further, a level shifter LS2 is supplied with the power supplies VPPSVT, VDD1, and VSS and increases the logic signal L2 in the VDD1 system to a logic signal L3 in the VPPSVT system. The logic signal L3 is connected to a gate of a PMOS transistor P31. A source and a drain of the PMOS transistor P31 are connected to the power supply VPPSVT and one end of the anti-fuse element Fuse, respectively. The other end of the anti-fuse element Fuse is connected to the power supply VBBSVT.

The logic signal L3 is also connected to a gate of a PMOS transistor P34 and a gate of an NMOS transistor N32. A source of the PMOS transistor P34 is connected to the power supply VPPSVT, and a drain of the PMOS transistor P34 is connected to a gate of a PMOS transistor P33 and a drain of an NMOS transistor N31. A gate of the NMOS transistor N31 is connected to the power supply VDD1, and a source of the NMOS transistor N31 is connected to a drain of the NMOS transistor N32. A source of the NMOS transistor N32 is connected to the power supply VSS, and a source of the PMOS transistor P33 is connected to the power supply VSS. A drain of the PMOS transistor P33 is connected to the drain of the PMOS transistor P31, one end of the anti-fuse element Fuse, and a first source/drain region of a PMOS transistor P32. A second source/drain region of the PMOS transistor P32 is connected to a gate of an inverter I1, which is a read circuit. The inverter I1 is a circuit in the power supply VDD2 system, and while not illustrated, the inverter I1 is connected to the power supplies VDD2 and VSS.

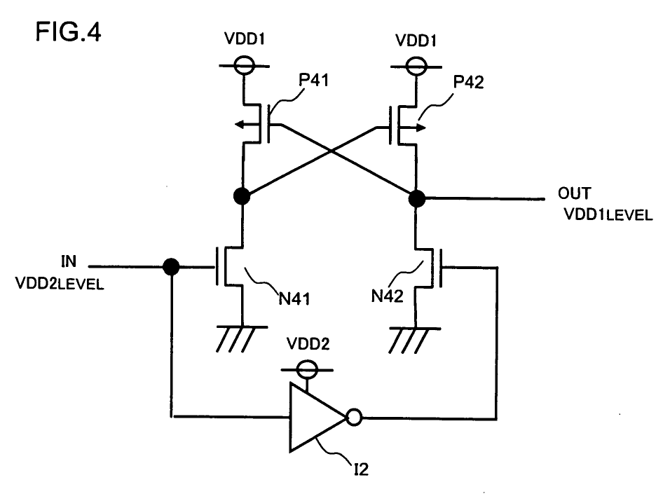

FIG. 4 illustrates an example of an internal configuration of the level shifter LS1. Since the internal configuration of the level shifter of FIG. 4 is known, detailed descriptions thereof will be omitted herein. In the level shifter LS2, the power supplies VDD2 and VDD1 are replaced with the power supplies VDD1 and VPPSVT, respectively. Other aspects of the circuit configuration of the level shifter LS2 are the same as those of the level shifter LS1 of FIG. 4.

Next, operations of the anti-fuse writing circuit of FIG. 3 will be described. As described above, during a write operation, the anti-fuse circuit 7 is supplied with five kinds of power supplies having power supply voltages VPPSVT (6.5 V), VDD1 (1.8 V), VDD2 (1.2 V), VSS (0 V), and VBBSVT (−3.5 V) in the order of highest to lowest. During a write operation, a VREADB signal is brought to be at a high level (VPPSVT level), and the inverter I1 is separated from the anti-fuse element Fuse. When the STORE signal is at a low level (0 V), the third logic signal L3 is also at a low level (0 V). Since the third logic signal L3 is at a low level, a current flows through the PMOS transistor P31. A current also flows through the PMOS transistor P34, and the NMOS transistor N32 is turned off. Thus, the power supply VPPSVT is applied to the gate of the PMOS transistor P33, and the PMOS transistor P33 is turned off. Further, since the power supply VDD1 is applied to the gate of the NMOS transistor N31, the power supply VPPSVT is not directly applied to the drain of the NMOS transistor N32. Namely, the electric field applied to the drain of the NMOS transistor N32 is relieved by the NMOS transistor N31.

In this state, since the PMOS transistor P31 is turned on and the PMOS transistor P33 is turned off, a potential difference between VPPSVT and VBBSVT is applied across the terminals of the anti-fuse element Fuse. Namely, since the anti-fuse element Fuse is supplied with a voltage exceeding a withstand voltage thereof, an insulating state between the terminals of the anti-fuse element Fuse is destroyed, and as a result, a current flows through the anti-fuse element Fuse. This current conduction through the anti-fuse element Fuse is irreversible, and once brought in a conducting state, the anti-fuse element Fuse cannot be brought in an insulating state again.

When a current is allowed to flow through the anti-fuse element Fuse, the high voltage VPPSVT is also applied to the source of the PMOS transistor P33 and the first source/drain region of the PMOS transistor P32. However, the voltage applied across the terminals of the anti-fuse element Fuse is greater than the source-drain voltages of the PMOS transistors P33 and P32. This is because the negative power supply voltage VBBSVT is applied to the other terminal of the anti-fuse element Fuse. Thus, even when the anti-fuse element Fuse undergoes dielectric breakdown, the PMOS transistors P32 and P33 are not brought under excessive voltage stress.

In contrast, when the STORE signal is at a high level (VDD2), the STORE signal is increased by the level shifters LS1 and LS2 in two stages, and as a result, the third logic signal L3 is brought at a high level (VPPSVT). When the potential difference to be increased is large between two power supplies, an operating margin of the level shift circuit illustrated in FIG. 4 is narrow. However, in this example, since the STORE signal is increased by two voltage-boost circuits in two stages, even when the potential difference between voltage levels of the initial logic signal and the resultant logic signal is large, a reliable operation of the anti-fuse circuit 7 can be secured. If necessary, three or more level shift circuits may be used. When the third logic signal L3 is brought at a high level, the PMOS transistor P31 and the PMOS transistor P34 are turned off, and the NMOS transistor N32 is turned on. Since the NMOS transistor N31 is also supplied with a fixed bias, the gate of the PMOS transistor P33 is supplied with a low-level voltage, the PMOS transistor P33 is turned on, and one terminal of the anti-fuse element Fuse is supplied with the voltage VSS. Thus, while the negative voltage VBBSVT is applied to the other terminal of the anti-fuse element Fuse, since the voltage across the terminals of the anti-fuse element Fuse does not exceed the withstand voltage thereof, the anti-fuse element Fuse is maintained in an insulating state.

During a read operation, the power supply VPPSVT is not supplied, and the power supply VBBSVT is brought at a voltage level equal to the power supply VSS. Since the power supply VPPSVT is not supplied, both of the PMOS transistors P31 and P33 are brought in an off state. In an initial period of a read operation, the VREADB signal is brought at a high level, the PMOS transistor P32 is brought in an off state. In this state, the read circuit side of the PMOS transistor P32 is precharged by a precharge circuit (not illustrated) to VDD2. Thereafter, the VREADB signal is brought at a low level, and the PMOS transistor P32 is switched from an off state to an on state. When the anti-fuse element Fuse is in an on state, the precharged VDD2-level electric charges flow to VSS (VBBSVT=VSS) via the PMOS transistor P32 and the anti-fuse element Fuse. Thus, the inverter I1 is supplied with a low level signal. In contrast, when the anti-fuse element Fuse is in an off state, the precharged VDD2-level electric charges are maintained, and the inverter I1 is supplied with a high level signal. In this way, the on/off state of the anti-fuse element Fuse can be detected. When a write programming operation is not executed on the anti-fuse element Fuse, the level shifters LS1 and LS2 may be turned off to reduce power consumption.

### Example 2

Next, an example where an anti-fuse circuit is used in a semiconductor memory device such as a dynamic random access memory (DRAM) will be described. FIG. 5 is a block diagram illustrating an overall configuration of a semiconductor memory device according to example 2. In FIG. 5, a semiconductor memory device 31 is a synchronous DRAM. An overall configuration of the semiconductor memory device 31 of FIG. 5 will be hereinafter described. A clock generator 1 receives clock signals CK and /CK and a clock enable signal CKE from the outside and supplies these clocks to the entire semiconductor memory device 31. An address bus 3 receives address signals A0 to A13 and bank address signals BA0 to BA2 from the outside and sends these signals to a mode register 2, a row address buffer/refresh counter 6, and a column address buffer/burst counter 8. The mode register 2 receives address data from the address bus 3 and sets an internal operation mode. A command decoder 4 receives a chip select signal /CS, a row address strobe signal /RAS, a column address strobe signal /CAS, and a write enable signal /WE from the outside and decodes commands supplied from the outside. A control logic 5 controls the entire semiconductor memory device 31 based on the commands decoded by the command decoder 4. The row address buffer/refresh counter 6 receives row addresses from the address bus 3 and counts refresh addresses. The column address buffer/burst counter 8 receives column addresses from the address bus 3 and counts burst transfer column addresses. In a memory cell array 10, DRAM cells are arranged in a matrix pattern, and the addresses thereof are specified by a row decoder 11 and a column decoder 13. The memory cell array 10 includes eight banks from banks 0 to 7. When data is read from the memory cell array 10 or when data is refreshed, a sense amplifier 12 amplifies the data read from the memory cell array 10 via bit lines. A data control circuit 14 controls data inputted to and outputted from the memory cell array 10. A latch circuit 15 temporarily stores data inputted to and outputted from the outside. A delay-locked loop (DLL) 16 generates clock signals in synchronization with the clock signals CK and /CK supplied from the outside and supplies the generated signals to an input-output buffer 17. The input-output buffer 17 is connected to an external data bus DQ and executes data input/output processing in synchronization with data strobe signals DQS and /DQS and differential data strobe signals RDQS and /RDQS. Further, the input-output buffer 17 receives a terminal resistance control signal ODT and a data mask signal DM.

Each bank of the memory cell array 10 includes a redundant memory cell row and column (not illustrated). When the memory cell array 10 is tested and a defective memory cell is found, a row or a column that includes the defective memory cell is replaced with the redundant memory cell row or column. Each anti-fuse circuit 7 arranged for the row decoder 11 and the column decoder 13 stores addresses of a row and a column including a defective memory cell which need to be replaced with the redundant memory cell row and column, respectively. When the row address buffer/refresh counter 6 and the column address buffer/burst counter 8 specify the row and column addresses including a defective memory cell, instead of the row and column addresses, the anti-fuse circuit 7 outputs the redundant memory cell row and column as the row and column address, respectively. Thus, the anti-fuse circuit 7 has a bit number corresponding to a bit number of a replaced row address and column address. Further, when a plurality of redundant memory cell rows and columns are arranged, necessary elements are correspondingly arranged. Further, while not illustrated in FIG. 5, each bank is provided with the anti-fuse circuits 7. Each of the anti-fuse circuits 7 may have the same circuit configuration as that of example 1.

A power supply voltage generation circuit 18 is supplied with first and second power supplies VDD and VSS from the outside and generates the power supplies VPPSVT, VH, VDD1, VDD2, VSS, and VBBSVT necessary for executing a write operation on the anti-fuse circuit and a read/write operation on the memory cell array. When the power supply VDD supplied from the outside has the same potential as the power supply VDD1 or VDD2, a voltage that is not supplied from the outside can be supplied from the voltages supplied from the outside. The power supply VH is a high voltage power supply (normally 2.7 V), which is a midpoint potential between the power supplies VPPSVT and VDD1, and is used as a power supply for a decode circuit and the like for the memory cell array. The power supply voltage generation circuit 18 may be arranged in a single portion in the semiconductor memory device 31 or separately arranged in portions of the semiconductor memory device 31, depending on necessary power supplies. Among the power supplies VPPSVT, VH, VDD1, VDD2, VSS, and VBBSVT, the power supply voltage generation circuit 18 may generate necessary power supplies, only when necessary. Generation of unnecessary power supplies may be stopped individually, thereby reducing power consumption. For example, when the power supplies VPPSVT and VBBSVT are used only to execute a write programming operation on the anti-fuse element Fuse, by avoiding generation of these power supplies in other situations, power consumption can be reduced.

### Example 3

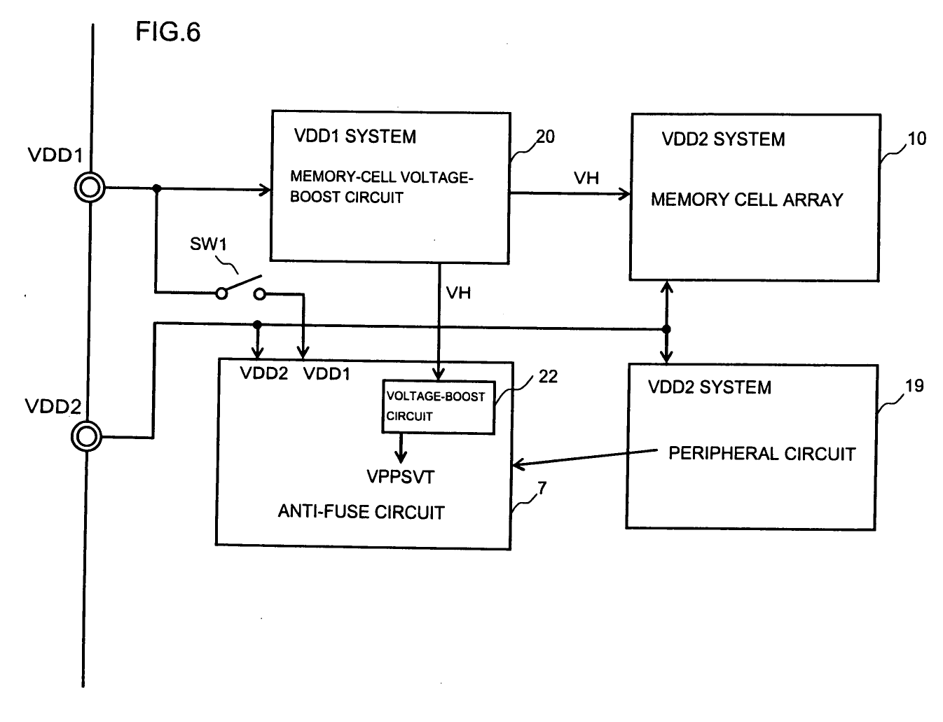

FIG. 6 illustrates power supply channels of a semiconductor memory device according to example 3. Example 3 is an example where the power supply voltage generation circuit 18 in example 2 is separately arranged in portions of the semiconductor memory device 31. FIG. 6 only illustrates power supply channels of the VDD2, VDD1, VH, and VPPSVT systems. In FIG. 6, both the power supplies VDD1 and VDD2 are supplied from the outside via external terminals VDD1 and VDD2. However, this is merely an example; only one of the power supplies VDD1 and VDD2 may be supplied from the outside, and the other power supply may be generated in the semiconductor memory device 31. In example 3, as in examples 1 and 2, the voltages VDD2, VDD1, VH, and VPPSVT are preferably 1.2 V, 1.8 V, 2.7 V, and 6.5 V, respectively.

The power supply VDD1 supplied from the external power supply terminal VDD1 is supplied to a memory-cell voltage-boost circuit 20 and a switch SW1. The memory-cell voltage-boost circuit 20 increases the supplied power supply VDD1 and generates the power supply VH. While the memory-cell voltage-boost circuit 20 supplies the power supply VH to the memory cell array 10 during a normal operation, it also supplies the power supply VH to the anti-fuse circuit 7. In addition to the configuration of FIG. 3, the anti-fuse circuit 7 includes a dedicated voltage-boost circuit 22 therein, which receives the power supply VH to generate the power supply VPPSVT for a write operation. This dedicated voltage-boost circuit 22 of the anti-fuse circuit 7 functions only when a write programming operation is executed on the anti-fuse element Fuse. Other than the write programming operation, the dedicated voltage-boost circuit 22 is stopped, thereby reducing power consumption. Further, the power supply VDD2 necessary for the operation of the memory cell array 10, the peripheral circuit 19, and the anti-fuse circuit 7 is supplied via the external terminal VDD2 to these individual elements. Furthermore, the peripheral circuit 19 supplies the anti-fuse circuit 7 with a control signal (STORE signal, for example).

The high-voltage power supply VH (2.7 V system) for the memory cell array is a power supply used when the memory cell array is accessed, and the power supply VH is not directly used by the anti-fuse circuit 7. However, in order to generate the power supply VPPSVT, which is higher than the high-voltage power supply VH, in the anti-fuse circuit 7, the power supply VH is supplied to the anti-fuse circuit 7 from the memory-cell voltage-boost circuit 20. Based on the high-voltage power supply VH supplied from the memory-cell voltage-boost circuit 20, the voltage-boost circuit 22 in the anti-fuse circuit 7 generates the higher voltage power supply VPPSVT therein, and in this way, the efficiency of generation of high-voltage power supplies is increased.

While various examples have thus been described, the present invention is not merely limited to the above examples. Needless to say, the present invention includes various variations and modifications that could be made by those skilled in the art within the scope of the present invention.

What is claimed is:

1. An anti-fuse circuit which uses first to fifth power supplies that have first to fifth power supply voltages, respectively, in an order of highest to lowest during writing, the anti-fuse circuit comprising:
a first level shift circuit which is coupled to the second to fourth power supplies and which converts a first logic signal that changes between the third and fourth power supply voltages into a second logic signal that changes between the second and fourth power supply voltages;
a second level shift circuit which is coupled to the first, second, and fourth power supplies and which converts the second logic signal into a third logic signal that changes between the first and fourth power supply voltages;
a transistor including a first source/drain region coupled to the first power supply and a gate coupled to the third logic signal; and
an anti-fuse element having one end coupled to a second source/drain region of the transistor and the other end coupled to the fifth power supply.

2. The anti-fuse circuit according to claim 1 further comprising, defining that the transistor is a first transistor, a second transistor including a first source/drain region coupled to said one end of the anti-fuse element, a second source/drain region coupled to a read circuit, and a gate coupled to a control signal that turns off the second transistor during writing and that turns on the second transistor during reading.

3. The anti-fuse circuit according to claim 2 further comprising a third transistor including a drain coupled to the fourth power supply and a source coupled to the second source/drain region of the first transistor, wherein a gate voltage of the third transistor is controlled such that the third transistor turns off and on when the first transistor turns on and off, respectively, during writing.

4. The anti-fuse circuit according to claim 3, further comprising:
a fourth transistor having a source coupled to the first power supply, a gate coupled to the third logic signal, and a drain coupled to the gate of the third transistor;
a fifth transistor having a source coupled to the fourth power supply and a gate coupled to the third logic signal; and
a sixth transistor having a source coupled to a drain of the fifth transistor, a gate coupled to the second power supply, and a drain coupled to the drain of the fourth transistor and the gate of the third transistor,
wherein the first to fourth transistors are MOS transistors of a first conductivity type, and the fifth and sixth transistors are MOS transistors of a conductivity type opposite to the first conductivity type.

5. The anti-fuse circuit according to claim 4, wherein the first power supply is not supplied during reading and both of the first and third transistors are turned off.

6. A semiconductor memory device comprising:
a memory cell array; and
an anti-fuse circuit which uses first to fifth power supplies that have first to fifth power supply voltages, respectively, in an order of highest to lowest during writing, the anti-fuse circuit comprising:
a first level shift circuit which is coupled to the second to fourth power supplies and which converts a first logic signal that changes between the third and fourth power supply voltages into a second logic signal that changes between the second and fourth power supply voltages;
a second level shift circuit which is coupled to the first, second, and fourth power supplies and which converts the second logic signal into a third logic signal that changes between the first and fourth power supply voltages;
a transistor including a first source/drain region coupled to the first power supply and a gate coupled to the third logic signal;
an anti-fuse element having one end coupled to a second source/drain region of the transistor and the other end coupled to the fifth power supply;
a first voltage-boost circuit which increases the second power supply to a midpoint potential between the first power supply and the second power supply and applies the increased potential to the memory cell array; and
a second voltage-boost circuit which further increases the potential increased by the first voltage-boost circuit to the first power supply when a write operation is executed on the anti-fuse circuit.

7. A semiconductor memory device according to claim 6, wherein the memory cell array comprises a redundant cell, and the anti-fuse circuit is used to select the redundant cell.

8. A semiconductor device comprising, on a single semiconductor chip:
a first level shift circuit receiving a logic signal which takes one of a first voltage and a second voltage larger than the first voltage and producing an intermediate signal which takes one of the first voltage and a third voltage larger than each of the first and second voltages;
a second level shift circuit receiving the intermediate signal and producing a control signal which takes one of the first voltage and a fourth voltage larger than each of the first, second and third voltages; and
an anti-fuse circuit including an anti-fuse element and receiving the fourth voltage, the anti-fuse circuit programming the anti-fuse element by supplying the fourth voltage to the anti-fuse element when the control signal takes the first voltage, and preventing the anti-fuse element from being supplied with the fourth voltage when the logic takes the fourth voltage.

9. The semiconductor device according to claim 8, further comprising first, second and third terminals on the single semiconductor chip, the first terminal being supplied with the first voltage from outside of the single semiconductor chip, the second terminal being supplied with the second voltage from outside of the single semiconductor chip, and the third terminal being supplied with the third voltage from outside of the third semiconductor chip, the first level shift circuit being connected to the first, second and third terminals to produce the intermediate signal, the second level shift circuit being connected to the first and third terminals and receiving the fourth voltage to produce the control signal.

10. The semiconductor device according to claim 9, further comprising first and second voltage-boost circuits on the single semiconductor chip, the first voltage-boost circuit being connected to the first and third terminals to generate a fifth voltage which is larger than each of the first, second and third voltages and smaller than the fourth voltage, and the second voltage-boost circuit being connected to the first terminal and receiving the fifth voltage to generate the fourth voltage.

11. The semiconductor device according to claim 10, further comprising a memory cell array on the single semiconductor chip, the first voltage-boost circuit supplying the memory cell array with the fifth voltage, the second voltage-boost circuit not supplying the memory cell array with the fourth voltage.

12. The semiconductor device according to claim 11, further comprising a peripheral circuit on the single semiconductor chip, the peripheral circuit being connected to the first and second terminals to be supplied with the first and second voltages, and not connected to the third terminal and not receiving the fourth and fifth voltages.
